(19) United States
(12) Patent Application Publication
(10) Pub. No.: US 2008/0017501 A1
(43) Pub. Date: Jan. 24, 2008

(54) COOLED DARK SPACE SHIELD FOR MULTI-CATHODE DESIGN

(76) Inventor: Makoto INAGAWA, Palo Alto, CA (US)

Correspondence Address: PATTERSON & SHERIDAN, LLP, 3040 POST OAK BOULEVARD, SUITE 1500, HOUSTON, TX, 77056, US

(21) Appl. No.: 11/780,474

(22) Filed: Jul. 20, 2007

Related U.S. Application Data
(60) Provisional application No. 60/820,023, filed on Jul. 21, 2006.

(51) Int. Cl. C23C 14/34; C23C 14/04; C23C 14/50

(52) U.S. Cl. 204/192.1; 204/298.11; 204/298.15

(57) ABSTRACT

A cooled dark space shield for a multi-cathode, large area PVD apparatus is disclosed. For multi-cathode systems, a dark space shield between adjacent cathodes/targets may be beneficial. The shields may be grounded and provide a path to ground for electrons present within a sputtering plasma. Because the shields are between adjacent targets, the grounded shields may contribute to the formation of a uniform plasma within the processing space by acting as anodes. As the temperatures in the chamber fluxuate between a processing temperature and a downtime temperature, the shields may expand and contract. Cooling the shields reduces the likelihood of expansion and contraction and thus, reduces the amount of flaking that may occur. Embossing the surface of the shields may reduce the amount of material deposited onto the shields and control the expansion and contraction of the shields.

### CROSS-REFERENCE TO RELATED APPLICATIONS

This application claims benefit of U.S. provisional patent application Ser. No. 60/820,023 (APPM/011337L), filed Jul. 21, 2006, which is herein incorporated by reference.

### BACKGROUND OF THE INVENTION

1. Field of the Invention

Embodiments of the present invention generally relate to a physical vapor deposition (PVD) system having a cooled dark space shield between adjacent sputtering targets.

2. Description of the Related Art

PVD using a magnetron is one method of depositing material onto a substrate. During a PVD process a target may be electrically biased so that ions generated in a process region can bombard the target surface with sufficient energy to dislodge atoms from the target. The process of biasing a target to cause the generation of a plasma that causes ions to bombard and remove atoms from the target surface is commonly called sputtering. The sputtered atoms travel generally toward the substrate being sputter coated, and the sputtered atoms are deposited on the substrate. Alternatively, the atoms react with a gas in the plasma, for example, nitrogen, to reactively deposit a compound on the substrate. Reactive sputtering is often used to form thin barrier and nucleation layers of titanium nitride or tantalum nitride on the substrate.

Direct current (DC) sputtering and alternating current (AC) sputtering are forms of sputtering in which the target is biased to attract ions towards the target. The target may be biased to a negative bias in the range of about −100 to '600 V to attract positive ions of the working gas (e.g., argon) toward the target to sputter the atoms. Usually, the sides of the sputter chamber are covered with a shield to protect the chamber walls from sputter deposition. The shield may be electrically grounded and thus provide an anode in opposition to the target cathode to capacitively couple the target power to the plasma generated in the sputter chamber.

During sputtering, material may sputter and deposit on the exposed surfaces within the chamber. The material deposited on the exposed surfaces of the chamber may flake off and contaminate the substrate. Therefore, there is a need in the art to reduce substrate contamination.

### SUMMARY OF THE INVENTION

A cooled dark space shield for a multi-cathode, large area PVD apparatus is disclosed. For multi-cathode systems, a dark space shield between adjacent cathodes/targets may be beneficial. The shields may be grounded and provide a path to ground for electrons present within a sputtering plasma. Because the shields are between adjacent targets, the grounded shields may contribute to the formation of a uniform plasma within the processing space by acting as anodes. As the temperatures in the chamber fluxuate between a processing temperature and a downtime temperature, the shields may expand and contract. Cooling the shields reduces the likelihood of expansion and contraction and thus, reduces the amount of flaking that may occur. Embossing the surface of the shields may reduce the amount of material deposited onto the shields and control the expansion and contraction of the shields.

In one embodiment, a sputtering target support frame assembly is disclosed. The assembly comprises an edge portion surrounding a plurality of targets, one or more beams spanning a length between adjacent targets, the one or more beams coupled with the edge portion, one or more dark space shields coupled with the one or more beams, and one or more cooling channels coupled with the one or more beams.

In another embodiment, a sputtering apparatus is disclosed. The apparatus comprises a plurality of sputtering targets and a target support frame coupled between a pair of sputtering targets of the plurality of sputtering targets. The target support frame comprises one or more beams having a ledge for supporting the pair of sputtering targets, one or more cooling channels coupled with the one or more beams, and one or more clamping mechanisms coupled with the one or more beams such that the pair of sputtering targets are coupled between the one or more clamping mechanisms and the ledge.

In another embodiment, an embossed dark space shield is disclosed. The shield comprises a shield body having at least one curved surface and a plurality of protrusions extending from the shield body.

In another embodiment, a sputtering method is disclosed. The method comprises coupling a sputtering target between one or more clamping mechanisms and a ledge of a support beam, the beam coupled with a dark space shield, providing a cooling channel proximate the dark space shield and the beam, flowing a cooling fluid within the cooling channel, and sputtering material from the sputtering target onto a substrate.

### BRIEF DESCRIPTION OF THE DRAWINGS

So that the manner in which the above recited features of the present invention can be understood in detail, a more particular description of the invention, briefly summarized above, may be had by reference to embodiments, some of which are illustrated in the appended drawings. It is to be noted, however, that the appended drawings illustrate only typical embodiments of this invention and are therefore not to be considered limiting of its scope, for the invention may admit to other equally effective embodiments.

FIG. 1 is a cross sectional view of a PVD apparatus 100 according to one embodiment of the invention.

FIG. 2 is a bottom view of a sputtering target assembly 200 according to one embodiment of the invention.

FIG. 3 is a schematic perspective view of a frame assembly 300 according to one embodiment of the invention.

FIG. 4 is a cross sectional view of a beam assembly between adjacent target assemblies according to one embodiment of the invention.

FIG. 5 is a cross sectional view of a beam assembly between adjacent target assemblies according to another embodiment of the invention.

FIG. 6 is a schematic perspective view of a dark space shield 600 according to one embodiment of the invention.

FIG. 7A is a top view of a protrusion 700 formed in the embossed surface of a dark space shield according to one embodiment of the invention.

FIG. 7B is a cross section of the protrusion 700 of FIG. 7A.

To facilitate understanding, identical reference numerals have been used, where possible, to designate identical elements that are common to the figures. It is contemplated that elements disclosed in one embodiment may be beneficially utilized on other embodiments without specific recitation.

### DETAILED DESCRIPTION

A cooled dark space shield for a multi-cathode, large area PVD apparatus is disclosed. For multi-cathode systems, a dark space shield between adjacent cathodes/targets may be beneficial. The shields may be grounded and provide a path to ground for electrons present within a sputtering plasma. Because the shields are between adjacent targets, the grounded shields may contribute to the formation of a uniform plasma within the processing space by acting as anodes. As the temperatures in the chamber fluxuate between a processing temperature and a downtime temperature, the shields may expand and contract. Cooling the shields reduces the likelihood of expansion and contraction and thus, reduces the amount of flaking that may occur. Embossing the surface of the shields may reduce the amount of material deposited onto the shields and control the expansion and contraction of the shields.

The invention is illustratively described and may be used in a PVD system for processing large area substrates, such as a PVD system, available from AKT®, a subsidiary of Applied Materials, Inc., Santa Clara, Calif. However, it should be understood that the sputtering target may have utility in other system configurations, including those systems configured to process large area round substrates. An exemplary system in which the present invention can be practiced is described in U.S. patent application Ser. No. 11/225,922, filed Sep. 13, 2005, which is hereby incorporated by reference in its entirety.

As the demand for larger flat panel displays increases, so must the substrate size. As substrate size increases, so must the size of the sputtering target. For flat panel displays and solar panels, sputtering targets having a length of greater than 1 meter are not uncommon. Producing a unitary sputtering target of substantial size from an ingot can prove difficult and expensive. For example, it is difficult to obtain large molybdenum plates (i.e., 1.8 m×2.2 m×10 mm, 2.5 m×2.8 m×10 mm, etc.) and quite expensive. Producing a large area molybdenum target requires a significant capital investment. A large area (i.e., 1.8 m×2.2 m×10 mm) one piece molybdenum target may cost as much as $15,000,000 to produce. Therefore, for cost considerations alone, it would be beneficial to utilize a plurality of smaller targets, but still achieve the deposition uniformity of a large area sputtering target. The plurality of targets may be the same composition or a different composition.

With increasing substrate and chamber size comes various challenges. Among those challenges is uniform deposition. Electrons within the sputtering plasma are attracted to elements within the apparatus that are grounded. Traditionally, the chamber walls and the susceptor or substrate support are grounded and thus, function as an anode in opposition to the sputtering target, which functions as the cathode.

The grounded chamber walls functioning as an anode attract electrons from the plasma and hence, may tend to create a higher density of plasma near the chamber walls. A higher density of plasma near the chamber walls may increase the deposition on the substrate near the chamber walls and decrease the deposition away from the chamber walls. The grounded susceptor, on the other hand, also functions as an anode. The susceptor may span a significant length of the processing space. Thus, the susceptor may provide a path to ground for electrons not only at the edge of the susceptor, but also at the middle of the susceptor. The path to ground at the middle of the susceptor balances out the path to ground at the edge of the susceptor and the chamber walls because each anode, be it the chamber walls or the susceptor, will equally function as an anode and uniformly spread the plasma across the processing space. By uniformly distributing the plasma across the processing space, uniform deposition across the substrate may occur.

When the substrate is an insulating substrate (such as glass or polymer), the substrate is non-conductive and thus electrons do not follow through the substrate. As a consequence, when the substrate substantially covers the substrate support, the substrate support does not provide sufficient anode surfaces.

For large area substrates, such as solar panels or substrates for flat panel displays, the size of the substrate blocking the path to ground through the susceptor may be significant. Substrates as large as 1 meter by 1 meter are not uncommon in the flat panel display industry. For a 1 meter by 1 meter substrate, a path to ground through the susceptor is blocked for an area of 1 square meter. Therefore, the chamber walls and the edges of the susceptor that are not covered by the substrate are the only paths to ground for the electrons in the plasma. No path to ground exists near the center of the substrate. With a large area substrate, a high density plasma may form near the chamber walls and the edge of the susceptor that are not covered by the substrate. The high density plasma near the chamber walls and the susceptor edge may thin the plasma near the center of the processing region where no path to ground exists. Without a path to ground near the center of the processing area, the plasma may not be uniform and hence, the deposition on the large area substrate may not be uniform.

To help ensure a uniform plasma, anodes, in addition to the susceptor and chamber walls, may be provided in the chamber. For a multi-cathode system where multiple sputtering target strips/panels are used, the anodes may be placed between adjacent sputtering target strips/panels.

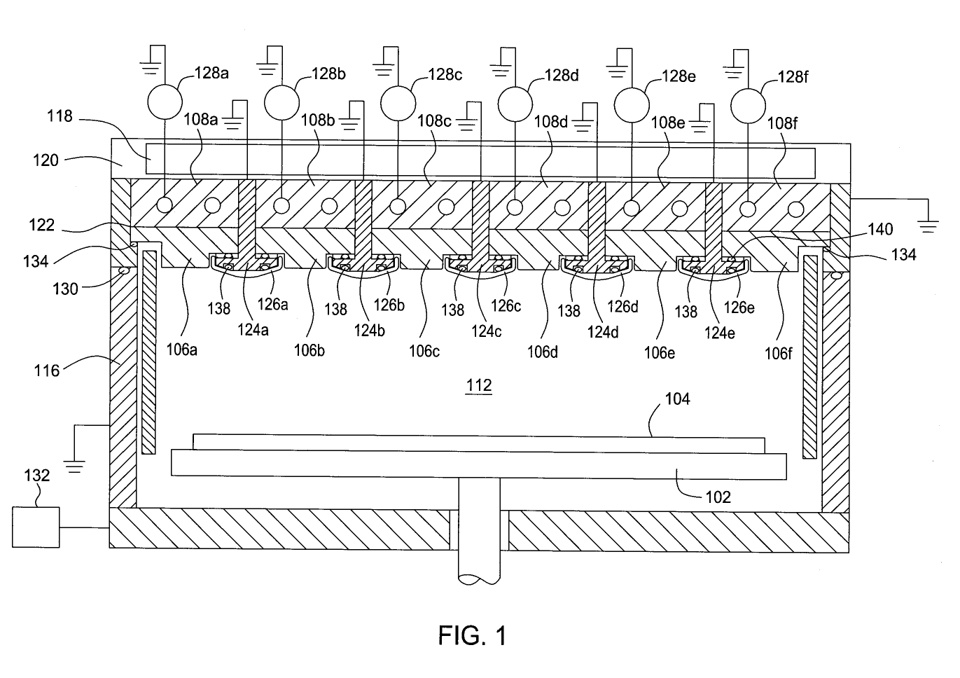

FIG. 1 is a cross sectional view of a PVD apparatus 100 according to one embodiment of the invention. The apparatus 100 comprises a substrate 104 supported on a susceptor 102 contained within the chamber walls 116 of the apparatus 100. The chamber walls 116 are grounded. The substrate 104 sits opposite a plurality of sputtering targets 106a-106f. Between the substrate 104 and the targets 106a-106f is the processing region 112. The chamber walls 116 are shielded from deposition by a shield 114.

In one embodiment, each sputtering target 106a-106f has a corresponding backing plate 108a-108f. In another embodiment, each sputtering target 106a-106f may be coupled with a single, common backing plate. While the invention will be described with reference to the former embodiment, it is to be understood that the descriptions are equally applicable to the single, common backing plate embodiment.

Within the backing plates 108a-108c are cooling channels. Cooling fluid is flowed through the cooling channels to control the temperature of the backing plates 108a-108f and hence, the sputtering targets 106a-106f. The cooling fluid may be any conventional cooling fluid known in the art. In one embodiment, the cooling fluid is water. In another embodiment, the cooling fluid is in the gaseous state.

A magnetron 118 is positioned in a magnetron chamber 120 that lies behind the backing plates 108a-108f. The magnetron 118 may be a stationary magnetron assembly or a movable magnetron assembly. In one embodiment, the magnetron 118 is a plurality of magnetron assemblies wherein the number of magnetrons 118 corresponds to the number of targets 106a-106f. When the number of magnetrons 118 corresponds to the number of targets 106a-106f, the magnetic field across each individual target may be controlled and adjusted.

The targets 106a-106f may be bonded to the backing plates 108a-108f by a bonding layer 122. The bonding layer 122 may be any conventionally known bonding material known in the art. Exemplary bonding material that may be used to bond the targets 106a-106f to the backing plates 108a-108f are disclosed in U.S. patent application Ser. No. 11/224,221, filed Sep. 12, 2005, which is hereby incorporated by reference in its entirety.

The sputtering targets 106a-106f may be disposed on a frame assembly. The frame assembly may have one or more beams 124a-124e that span the processing space 112. The frame assembly may also have a ledge 134 coupled with the frame assembly. The sputtering targets 106a-106f may be disposed onto the ledge 134 and beams 124a-124e so that the sputtering targets 106a-106f rest on the ledge 134 and beams 124a-124e. The sputtering targets 106a-106f may be electrically isolated from the beams 124a-124e and ledge 134 by electrical insulators 140.

Each target 106a-106f may be coupled with a corresponding power source 128a-128f so that each target 106a-106f may be individually powered. By providing a separate power source 128a-128f to each target 106a-106f, the power level to each target 106a-106f may be individually controlled to achieve a uniform deposition. The power source 128a-128f may be DC, AC, pulsed, RF, or a combination thereof. The apparatus may be controlled by a controller 132. An exemplary power configuration is described in U.S. patent application Ser. No. 11/428,226, filed Jun. 30, 2006, which is hereby incorporated by reference in its entirety.

The beams 124a-124e and ledge 134 that comprise the frame assembly may be grounded so that the frame assembly functions as an anode. In one embodiment, the frame assembly including the beams 124a-124e and ledge 134 may comprise a unitary structure. Each beam 124a-124e has a corresponding dark space shield 126a-126e coupled therewith. The dark space shields 126a-126e protect the beams 124a-124e from unwanted deposition and may be electrically coupled to the beams 124a-124e so that the dark space shields 126a-126e function as anodes. In one embodiment, the dark space shields 126a-126e may be made from the same material as the sputtering target. In another embodiment, the dark space shields 126a-126e may be made from stainless steel, bead blasted, and flame sprayed with aluminum or the same material as the sputtering target.

The dark space shields 126a-126e may be exposed to the processing area 112 and thus may experience significant changes in temperature between processing and downtime. To compensate for temperature fluxuations, the dark space shields 126a-126e may be cooled by flowing a cooling fluid through cooling channels 138. The dark space shields 126a-126e may be removably coupled with the beams 124a-124e.

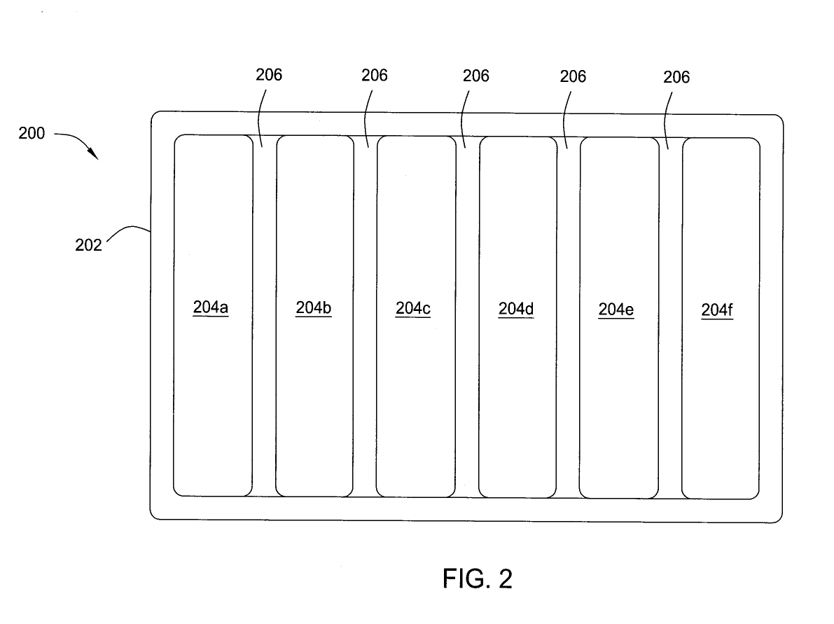

FIG. 2 is a bottom view of a sputtering target assembly 200 according to one embodiment of the invention. A plurality of sputtering targets 204a-204f may be spaced across the sputtering target assembly 200 and disposed in a frame assembly 202. The frame assembly 202 may comprise one or more beams 206. In one embodiment, the frame assembly 202 comprises a unitary piece of material. It is to be understood that while six sputtering targets 204a-204f have been shown, more or less sputtering targets 204a-204f may be used. Additionally, while the sputtering targets 204a-204f have been shown as sputtering target strips, other configurations are also contemplated by the invention. For example, sputtering target tiles and sputtering target tiles coupled together to make sputtering target strips may be used. Exemplary sputtering target tiles that have been coupled together to make sputtering target strips is described in U.S. patent application Ser. No. 11/424,467, filed Jun. 15, 2006 and U.S. patent application Ser. No. 11/424,478, filed Jun. 15, 2006, both of which are hereby incorporated by reference in their entirety.

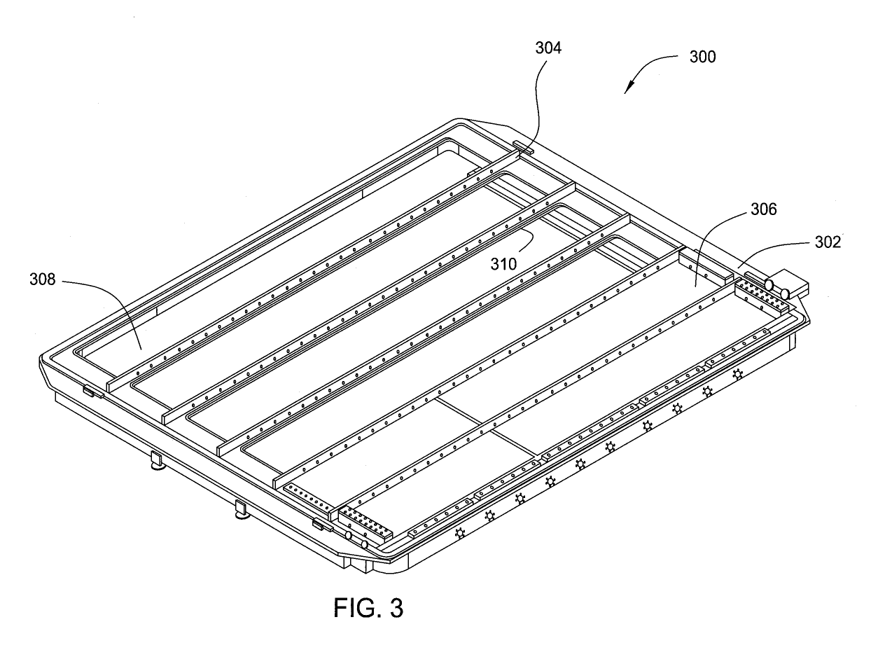

FIG. 3 is a schematic perspective view of a frame assembly 300 according to one embodiment of the invention. The frame assembly 300 may comprise one or more beams 304 that extend between the outer frame portion 302. The sputtering target assemblies 306 may rest within the openings 308 within the frame assembly 300 upon ledges 310 disposed on the beams 304 and the outer frame portion 302.

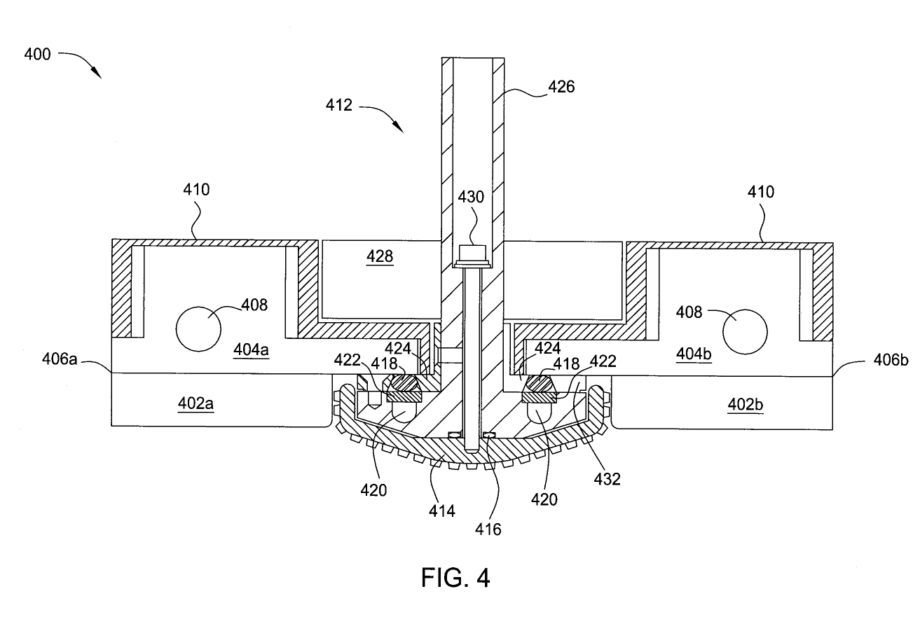

FIG. 4 is a cross sectional view of a beam assembly between adjacent target assemblies according to one embodiment of the invention. The target assemblies each include a sputtering target 402a, 402b, bonded to a backing plate 404a, 404b with a bonding layer 406a, 406b. The temperature of the backing plates 404a, 404b may be controlled with one or more cooling channels 408 that may be present in the backing plate 404a, 404b. A backing plate coating 410 may be present on the back side of the backing plate 404a, 404b to facilitate movement of a magnetron (not shown) across the back surface of the backing plate 404a, 404b and to insulate the magnetron.

The beam assembly 412 may comprise a beam body 426 coupled with a dark space shield 414. A clamp 428 may be disposed through the beam body 426. A coupling mechanism 430 may secure the clamp 428 to the beam body 426 and thus secure the sputtering target assembly between the clamp 428 and a ledge 432 of the beam body 426. The sputtering target assembly may be electrically isolated from the beam body 426 by an electrically insulating member 424. The dark space shield 414 may be coupled with the beam assembly 412 by any conventional attachment means known in the art. Likewise, the insulating member 424 may be coupled with the beam assembly 412 by any conventional attachment means known in the art. Sealing members 416 may be present between the dark space shield 414 and the beam body 426. Additional sealing members 418 may be present between the backing plate 404a, 404b and the beam assembly 412. As noted above, the beam assembly 412 and hence, the dark space shield 414 may be grounded and thus effectively function as an anode.

The unique design of multi-cathode PVD apparatus permits the anodes to be placed out of the processing space, yet still contribute to plasma uniformity. For multiple sputtering target strips spaced across a common backing plate (or each sputtering target with its own backing plate), a space exists between the adjacent sputtering targets. The space between the targets prevents arcing. Placing an anode in the space between the adjacent targets would be beneficial because the anodes would help reduce arcing. The placement of the beam assemblies 412 between the target assemblies is beneficial because the beam assemblies 412 do not block any line of sight path between the sputtering targets 402a, 402b and the substrate. By placing the beam assemblies 412 adjacent the targets 402a, 402b, any shadowing of the substrate by the anodes may be reduced.

It may be necessary for the beam assembly 412 to extend into the processing space beyond the sputtering targets 402a, 402b. As material is sputtered off of the sputtering targets 402a, 402b, it may travel in all directions. Thus, material sputtered from the targets 402a, 402b may deposit on the beam assembly 412. Therefore, the dark space shield 414 is coupled with the beam assembly 412. Any material sputtered from the targets 402a, 402b may deposit on the dark space shield 414 rather that the beam assembly 412. The dark space shield 414 may be replaced and/or cleaned so that the beam assembly 412 may be re-used indefinitely. The dark space shield 414 may be uncoupled from the beam assembly 412 whenever the dark space shield 414 needs to be replaced and/or cleaned. The dark space shield 414 may be angled to reduce the amount of material that may deposit on the dark space shield 414.

The temperatures within a PVD apparatus 400 may fluxuate between a processing temperature and a down-time temperature. A processing temperature may be so high as to turn the chamber components “red hot”. A down-time temperature may be as low as room temperature. As the temperature fluxuates, the dark space shield 414 may expand and contract. When the dark space shield 414 expands and contracts, material that is deposited on the dark space shield 414 may flake off and contaminate the substrate. Additionally, the processing temperature may approach or exceed the melting point of the sputtering material. Should any of the sputtering material be on the dark space shield 414 and reach the melting point of the sputtering material, the deposited material may drip off of the dark space shield 414 and contaminate the substrate. Controlling the temperature of the dark space shield 414 is beneficial because expansion and contraction of the dark space shield 414 may be reduced. Additionally, the temperature of the dark space shield 414 may be controlled to remain below the melting point of the sputtering material and hence, reduce any dripping onto the substrate.

Within the beam body 426 at least one cooling channel 420 may be present. The cooling channel 420 may thus be proximate both the beam body 426 and the dark space shield 414. The cooling channel 420 may be a continuous channel passing through the body 426 of the beam assembly 412 or it may be a plurality of cooling channels 420. The cooling channel 420 is sealed with a sealing member 422 to ensure that no cooling fluid enters the processing space and contaminates the substrate. The cooling fluid may be any conventional cooling fluid known in the art. In one embodiment, the cooling fluid is water. In another embodiment, the cooling fluid is in the gaseous state.

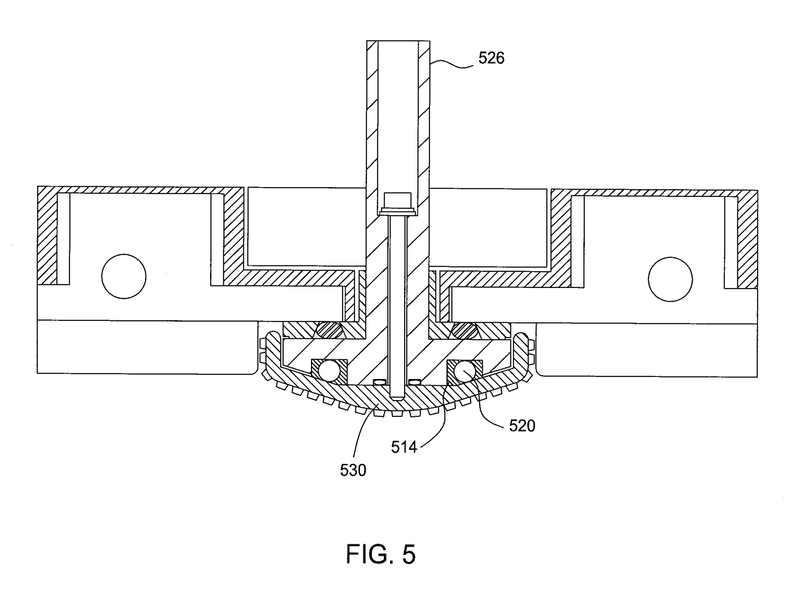

FIG. 5 is a cross sectional view of a beam assembly between adjacent target assemblies according to another embodiment of the invention. The cooling channel 520 may be disposed in a carved out portion of the dark space shield 530 and surrounded by a cooling channel frame 514. The cooling channel 520 is thus proximate the beam body 526.

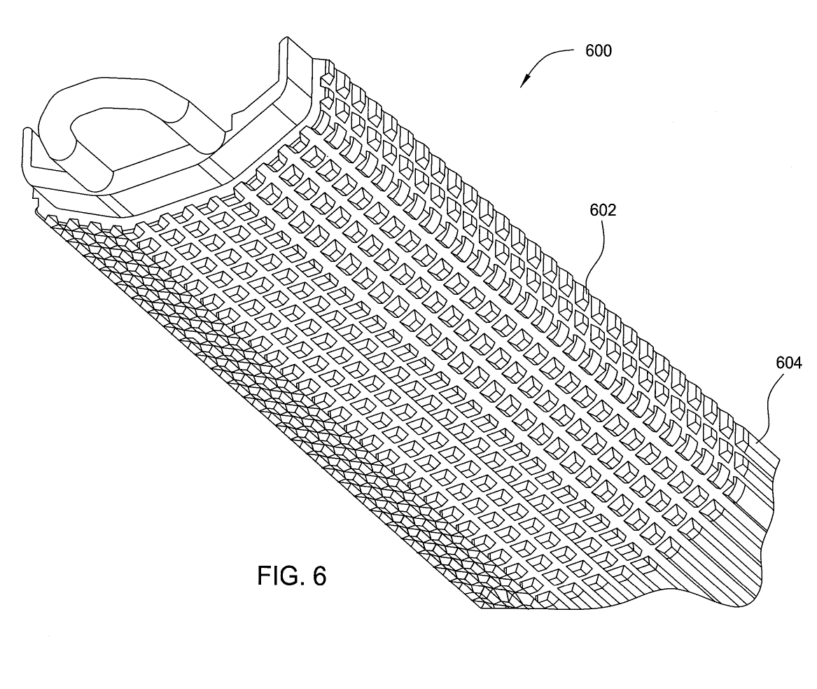

FIG. 6 is a schematic perspective view of a dark space shield 600 according to one embodiment of the invention. In one embodiment, the dark space shield 600 may be embossed so that one or more protrusions 602, 604 are present on the surface facing the processing space within the PVD chamber. The protrusions 602, 604 may be individual, substantially square shaped protrusions 602, elongated rectangular shaped protrusions 604, or combinations thereof. The protrusions 602, 604 on the dark space shield 600 provide smaller surfaces upon which sputtered material may deposit during sputtering. However, the embossed surface of the dark space shield 600 may be beneficial during any potential expansion and contraction of the dark space shield 600. During temperature changes, the protrusions 602, 604 may expand and contract rather than the entire dark space shield 600. Thus, the protrusions 602, 604 may reduce the amount of flaking that may occur. In one embodiment, the protrusions 602 have a surface area of about 25 square millimeters. Embossing, as opposed to simply roughening the surface by a process such as bead blasting, is beneficial because it provides a greater surface area to permit a greater amount of material to deposit onto the dark space shield 600 before replacement. Embossing may permit the dark space shield 600 to last up to about twice as long as a roughened dark space shield.

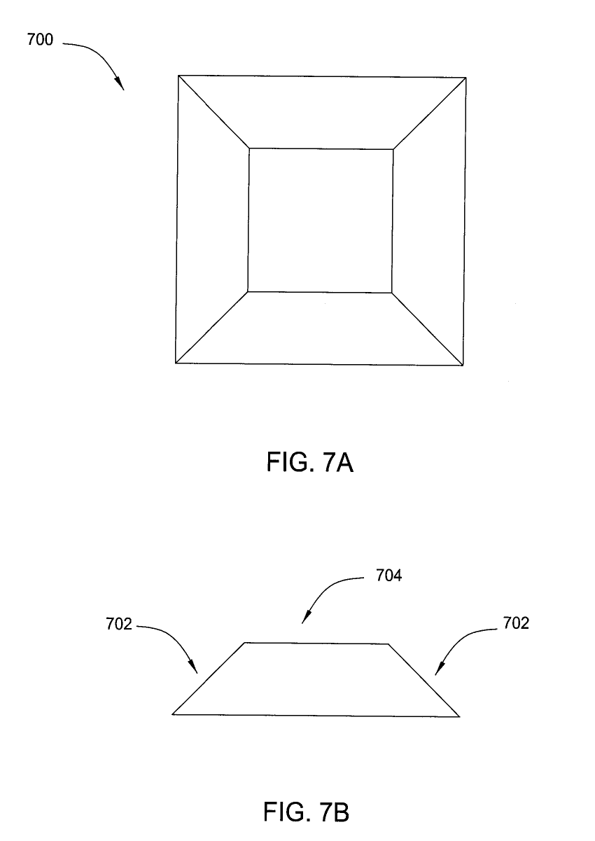

FIG. 7A is a top view of a protrusion 700 formed in the embossed surface of a dark space shield according to one embodiment of the invention. FIG. 7B is a cross section of the protrusion 700 of FIG. 7A. The protrusion 700 may have a slanted surface 702 as well as a substantially flat top surface 704. In one embodiment, the slanted surface 702 may be slanted at an angle of greater than about 25 degrees.

Positioning cooled dark space shield that function as anodes between adjacent targets in a multi-cathode PVD system may be beneficial because shadowing may be reduced and plasma uniformity may be increased. Cooling and embossing the dark space shields may reduce flaking or dripping and thus, reduce substrate contamination.

While the foregoing is directed to embodiments of the present invention, other and further embodiments of the invention may be devised without departing from the basic scope thereof, and the scope thereof is determined by the claims that follow.

1. A sputtering target support frame assembly, comprising:
an edge portion surrounding a plurality of targets;
one or more beams spanning a length between adjacent targets, the one or more beams coupled with the edge portion;
one or more dark space shields coupled with the one or more beams; and
one or more cooling channels coupled with the one or more beams.

2. The assembly of claim 1, wherein the one or more dark space shields are embossed.

3. The assembly of claim 2, wherein the one or more embossed dark space shields comprise a plurality of projections extending from the one or more dark space shields, the projections having a plurality of surfaces angled relative to each other.

4. The assembly of claim 3, wherein the projections have a surface area of about 25 mm².

5. The assembly of claim 1, further comprising:
one or more clamping mechanisms coupled with the one or more beams.

6. The assembly of claim 5, wherein the one or more clamping mechanisms are disposed through the one or more beams.

7. The assembly of claim 1, wherein the dark space shield comprises one or more grooves for disposing therein the one or more cooling channels.

8. The assembly of claim 1, wherein the one or more beams comprise one or more grooves for disposing therein the one or more cooling channels.

9. The assembly of claim 1, wherein the edge portion and the one or more beams comprise a unitary piece of material.

10. The assembly of claim 1, wherein the one or more dark space shields are removably coupled with the one or more beams.

11. A sputtering apparatus, comprising:
a plurality of sputtering targets; and
a target support frame coupled between a pair of sputtering targets of the plurality of sputtering targets, the target support frame comprising:
one or more beams having a ledge for supporting the pair of sputtering targets;
one or more cooling channels coupled with the one or more beams; and
one or more clamping mechanisms coupled with the one or more beams such that the pair of sputtering targets are coupled between the one or more clamping mechanisms and the ledge.

12. The apparatus of claim 11, further comprising a dark space shield coupled with the one or more beams.

13. The apparatus of claim 12, wherein the dark space shield has an embossed surface.

14. The apparatus of claim 13, wherein the embossed surface comprises a plurality of projections each having a plurality of surfaces extending from the dark space shield and angled relative to each other.

15. The apparatus of claim 14, wherein the projections have a surface area of about 25 mm².

16. The apparatus of claim 12, wherein the dark space shield is removably coupled with the one or more beams.

17. The apparatus of claim 12, wherein the dark space shield comprises one or more grooves for disposing therein the one or more cooling channels.

18. The apparatus of claim 12, wherein the one or more beams comprise one or more grooves for disposing therein the one or more cooling channels.

19. An embossed dark space shield, comprising:
a shield body having at least one curved surface; and
a plurality of protrusions extending from the shield body.

20. The shield of claim 19, wherein the protrusions comprise a substantially planar surface and at least one surface slanted relative to the substantially planar surface.

21. The shield of claim 19, wherein at least one protrusion is disposed on the at least one curved surface.

22. A sputtering method, comprising:
coupling a sputtering target between one or more clamping mechanisms and a ledge of a support beam, the beam coupled with a dark space shield;
providing a cooling channel proximate the dark space shield and the beam;
flowing a cooling fluid within the cooling channel; and
sputtering material from the sputtering target onto a substrate.

23. The method of claim 22, further comprising:
electrically isolating the ledge from the sputtering target.

24. The method of claim 22, wherein the dark space shield comprises an embossed surface having a plurality of projections each having a plurality of surfaces extending from the dark space shield, the method further comprising:
expanding and contacting the plurality of projections.

25. The method of claim 22, further comprising grounding the dark space shield.

26. The method of claim 22, wherein the substrate has a surface area of 1 square meter or greater.

27. The method of claim 22, wherein the cooling channel is disposed within the beam.

28. The method of claim 22, wherein the cooling channel contacts the dark space shield.
